(19) United States
(12) Patent Application Publication
(10) Pub. No.: US 2025/0218729 A1
(43) Pub. Date: Jul. 3, 2025

(54) SHOWER HEAD ASSEMBLY AND SUBSTRATE PROCESSING APPARATUS

(71) Applicant: SEMES CO., LTD., Cheonan-si (KR)

(72) Inventors: Jae Hwan KIM, Cheonan-si (KR); Wan Jae PARK, Cheonan-si (KR); Seong Gil LEE, Cheonan-si (KR); Joun Taek KOO, Cheonan-si (KR)

(73) Assignee: SEMES CO., LTD., Cheonan-si (KR)

(21) Appl. No.: 19/004,426

(22) Filed: Dec. 29, 2024

(30) Foreign Application Priority Data
Dec. 29, 2023 (KR) 10-2023-0197015

(51) Int. Cl. H01J 37/32

(52) U.S. Cl. CPC H01J 37/3244; H01J 2237/334

(57) ABSTRACT

Proposed are a shower head assembly and a substrate processing apparatus including the same. The shower head assembly includes a shower head for discharging a process gas into a substrate processing space of a process chamber, and a blocking airflow forming unit configured to block discharge of the process gas by forming a blocking airflow within the shower head, which passes through the inside of the shower head in a direction perpendicular to a discharge direction of the process gas. According to the shower head assembly, the amount of process gas supplied to the substrate processing space may be precisely controlled.

### CROSS REFERENCE TO RELATED APPLICATION

The present application claims priority to Korean Patent Application No. 10-2023-0197015, filed Dec. 29, 2023, the entire contents of which is incorporated herein for all purposes by this reference.

### BACKGROUND OF THE INVENTION

### Field of the Invention

The present disclosure relates to a shower head assembly having a shower head that sprays process gas required for a substrate processing process, and a substrate processing apparatus including the same.

Description of the Related Art

To manufacture semiconductors, various substrate processing processes need to be performed. Among the substrate processing processes for semiconductor manufacturing, etching, thin film deposition, ion implantation, and cleaning are performed by substrate processing apparatuses that use process gases.

Typically, a substrate processing apparatus using process gases includes a process chamber, a substrate support unit, and a shower head. The process chamber provides a substrate processing space, the substrate support unit supports a substrate in the substrate processing space, and the shower head discharges process gas from a process gas supply unit toward the substrate supported by the substrate support unit.

When performing a substrate processing process by such a substrate processing apparatus, it is necessary to control the amount of process gas supplied to the substrate processing space through supply and supply interruption of the process gas. In this case, the process gas supply unit is controlled to supply the process gas or stop the supply of the process gas. However, control through the process gas supply unit has the problem that even if the supply of process gas is stopped, the process gas remaining in a line of the process gas supply unit and inside the shower head is additionally supplied, and that when the supply of process gas is initiated, the supply of the process gas is delayed during the time required for the transport of the process gas, making it difficult to precisely control the amount of the process gas.

Meanwhile, in order to process a substrate uniformly, controlling the amount of process gas discharged from the shower head for each area of the shower head is necessary, and there is a need for improvement measures to easily implement this.

### DOCUMENTS OF RELATED ART

(Patent Document 0001) Korean Patent No. 10-0400044 (Sep. 29, 2003)

(Patent Document 0002) Korean Patent No. 10-2217160 (Feb. 19, 2021)

### SUMMARY OF THE INVENTION

Accordingly, the present disclosure has been made keeping in mind the above problems occurring in the related art, and the present disclosure is intended to provide a shower head assembly for more precise control of process gas supply, and a substrate processing apparatus including the same.

An objective of the present disclosure is to provide a shower head assembly for more even substrate processing, and a substrate processing apparatus including the same.

The objectives to be achieved are not limited to this, and other objectives not mentioned can be clearly understood by those skilled in the art from the following description.

In order to achieve the above objectives, according to an embodiment of the present disclosure, there is provided a shower head assembly including: a shower head for discharging a process gas into a substrate processing space; and a blocking airflow forming unit configured to block discharge of the process gas by forming a blocking airflow flowing in a direction intersecting a discharge direction of the process gas inside the shower head.

The shower head may be configured to allow the blocking airflow to pass therethrough. The shower head may have a gas supply port through which a gas of the blocking airflow is supplied and a gas discharge port through which the gas of the blocking airflow is discharged, provided opposite to each other. The blocking airflow forming unit may include: a gas supply module configured to supply the gas to the gas supply port; and a gas discharge module configured to regulate an amount of the gas discharged through the gas discharge port.

The shower head may include a shower plate, wherein the shower plate may have a plurality of process gas discharge holes passing therethrough, and a cavity communicating with the plurality of process gas discharge holes is formed therein, and the blocking airflow forming unit may form the blocking airflow in the cavity.

The shower plate may include at least one partition dividing the cavity into a plurality of blocked spaces communicating with the process gas discharge holes for each region of the shower plate, and the blocking airflow forming unit may form the blocking airflow in the blocked spaces individually.

The partition may be provided to circumferentially partition the cavity.

The shower plate may have a plurality of gas supply ports and gas discharge ports each communicating with the respective blocked spaces, and

The blocking airflow forming unit may include: a gas supply module configured to supply a gas of the blocking airflow to the gas supply ports; and a gas discharge module configured to regulate an amount of the gas discharged through the gas discharge ports. The gas discharge module may be maintained in a state to block discharge of the gas through the gas discharge ports, and, when the gas is supplied by the gas supply module to any blocked space selected among the blocked spaces, may be operated to allow the discharge of the gas from the selected blocked space at a time lag.

The shower head assembly according to an embodiment of the present disclosure may control distribution of the process gas in the substrate processing space by forming the blocking airflow in any blocked space selected among the blocked spaces.

The shower head may include a shower plate having a plurality of process gas discharge holes, and may be configured to have a buffer space provided for introducing the process gas and communicating with the plurality of process gas discharge holes, and the blocking airflow forming unit may form the blocking airflow in the buffer space. The shower head may be configured to allow the blocking airflow to pass through the buffer space.

The shower plate is provided in plural, wherein the shower plates may be stacked so that the process gas discharge holes match each other, and each of the shower plates may include at least one partition dividing the cavity into a plurality of blocked spaces in a circumferential direction, with the blocked spaces being arranged in different areas of the shower plates, and the blocking airflow forming unit may individually form the blocking airflow in the blocked spaces of the shower plates.

A gas of the blocking airflow may be an inert gas. A flow rate of the blocking airflow may be faster than a flow rate of the process gas.

According to an embodiment of the present disclosure, there may be provided a substrate processing apparatus including: a process chamber configured to provide a substrate processing space; a substrate support unit configured to support a substrate in the substrate processing space; a shower head configured to discharge a process gas from a process gas supply unit into the substrate processing space; a plasma source configured to generate plasma from the process gas supplied to the substrate processing space; and a blocking airflow forming unit configured to block discharge of the process gas by forming a blocking airflow flowing in a direction intersecting a discharge direction of the process gas inside the shower head.

In the substrate processing apparatus according to an embodiment of the present disclosure, the shower head may include a shower plate having a plurality of process gas discharge holes, may have a buffer space provided for introducing the process gas and communicating with the plurality of process gas discharge holes, and may be configured to allow the blocking airflow to pass therethrough.

In addition, in the substrate processing apparatus according to an embodiment of the present disclosure, the shower plate may have a cavity formed therein communicating with the plurality of process gas discharge holes, and may include at least one partition dividing the cavity into a plurality of blocked spaces communicating with the plurality of process gas discharge holes for each region of the shower plate, and the blocking airflow forming unit may form the blocking airflow in the blocked spaces individually. The partition may be provided to circumferentially partition the cavity.

According to an embodiment of the present disclosure, there may be provided a substrate processing apparatus including: a process chamber configured to provide a substrate processing space; a substrate support unit configured to support a substrate in a lower area of the substrate processing space; a shower head configured to discharge a process gas supplied from a process gas supply unit onto the substrate supported by the substrate support unit from an upper area of the substrate processing space; a plasma source configured to generate plasma from the process gas supplied to the substrate processing space; and a blocking airflow forming unit configured to block discharge of the process gas by forming a blocking airflow flowing at a faster flow rate than that of the process gas in a direction perpendicular to a discharge direction of the process gas inside the shower head, wherein the shower head may include a shower plate having a plurality of process gas discharge holes, and may have a buffer space provided for introducing the process gas and communicating with the plurality of process gas discharge holes, the shower plate may have a cavity formed therein communicating with the plurality of process gas discharge holes, may include at least one partition dividing the cavity into a plurality of circumferentially partitioned blocked spaces, and may have a plurality of gas supply ports and gas discharge ports each communicating with the respective blocked spaces, the blocking airflow forming unit may be configured to individually supply a gas of the blocking airflow to the gas supply ports and individually adjust an amount of the gas discharged through the gas discharge ports, and the gas of the blocking airflow may be an inert gas.

The technical solutions will become more specific and clearer through the embodiments and drawings described below. In addition, various solutions other than those mentioned below may be additionally presented.

According to an embodiment of the present disclosure, the amount of process gas supplied to a substrate processing space can be precisely and accurately controlled during a substrate processing process. Furthermore, according to an embodiment of the present disclosure, during a substrate processing process, the distribution of process gas within the substrate processing space can be controlled. Therefore, improved precision, uniformity, and efficiency of substrate processing can be guaranteed.

The advantageous effects are not limited to this, and other effects not mentioned can be clearly understood by those skilled in the art from the present specification and the attached drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic view showing a substrate processing apparatus according to an embodiment of the present disclosure;

FIG. 2 is a schematic view showing a substrate support assembly illustrated in FIG. 1;

FIG. 3 is a schematic view showing a shower head assembly illustrated in FIG. 1;

FIG. 4 is a cross-sectional perspective view showing a shower plate illustrated in FIG. 3;

FIGS. 5 to 8 show the configuration and operation of the shower head assembly illustrated in FIG. 3; and

FIG. 9 is a cross-sectional view showing a modified example of the shower head assembly illustrated in FIG. 3, focusing on the main parts of the shower head assembly.

### DETAILED DESCRIPTION OF THE INVENTION

Hereinafter, embodiments of the present disclosure will be described in detail with reference to the accompanying drawings so that those skilled in the art can easily carry out the present disclosure. However, the present disclosure may be embodied in many different forms and is not limited to the embodiments described herein.

In describing the embodiments of the present disclosure, when it is determined that a detailed description of a related known function or configuration may unnecessarily obscure the subject matter of the present disclosure, the specific description will be omitted, and parts with similar functions and actions will use the same reference numerals throughout the drawings.

Since at least some of the terms used in the specification are defined in consideration of functions in the present disclosure, they may vary according to user, operator intention, custom, and the like. Therefore, the terms should be interpreted based on the contents throughout the specification. In addition, in this specification, when a certain component is said to be included, this means that other components may also be included without excluding other components unless otherwise stated. When a part is said to be connected (or coupled) with another part, this includes not only the case of being directly connected (or coupled), but also the case of being indirectly connected (or coupled) with another part in between.

Meanwhile, in the drawings, the size or shape of components, and thickness of lines may be somewhat exaggerated for convenience of understanding.

A shower head assembly for a substrate processing apparatus according to an embodiment of the present disclosure may be used for substrate processing processes such as etching, ashing, and deposition. The embodiment of the present disclosure will be described mainly with reference to a substrate that is a circular wafer, and a substrate processing apparatus having a shower head, which is a dry etcher that performs an etching process among apparatuses using plasma.

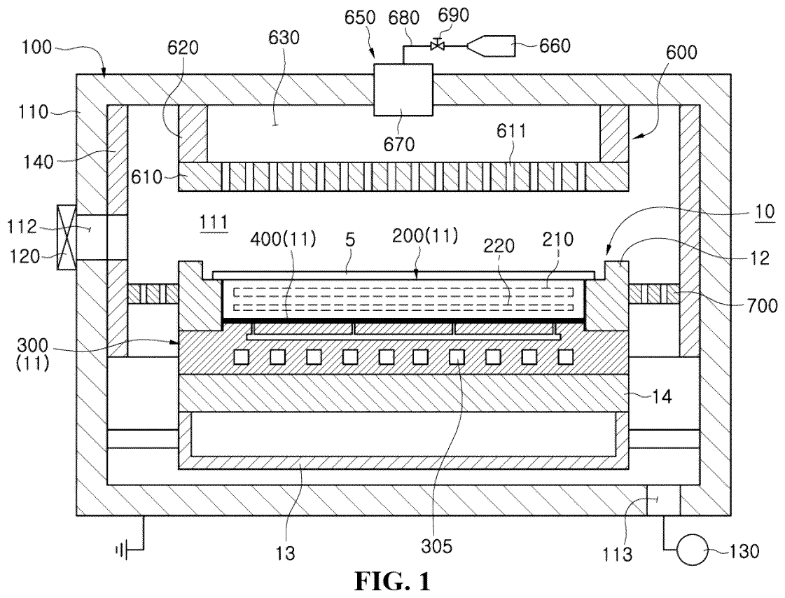

The overall configuration of a substrate processing apparatus according to an embodiment of the present disclosure is illustrated in FIG. 1. The substrate processing apparatus according to an embodiment of the present disclosure is configured to perform an etching process using plasma as a processing process for a substrate. Referring to FIG. 1, to be specific, the substrate processing apparatus according to an embodiment of the present disclosure includes a process chamber 100, a substrate support assembly 10, a shower head 600, a process gas supply unit 650, an electromagnetic field forming unit (plasma source), and a baffle unit 700. In order to perform a substrate processing process, the substrate support assembly 10 supports a substrate 5. Then, the process gas supply unit 650 supplies a process gas to the inside (substrate processing space) of the process chamber 100 using the shower head 600. Then, the electromagnetic field forming unit forms an electromagnetic field inside the process chamber 100 to excite the process gas supplied inside the process chamber 100 into a plasma state.

The process chamber 100 is configured to have a substrate processing space 111 that may be blocked from the outside. The substrate 5 may be processed by plasma in the substrate processing space 111 when a substrate processing process is performed. The process chamber 100 includes a chamber body 110. The substrate processing space 111 is formed inside the chamber body 110. The chamber body 110 may be provided as metal and may be grounded. For example, the material of the chamber body 110 may be aluminum (Al).

The chamber body 110 has a substrate entrance 112 communicating with the substrate processing space 111. For example, the substrate entrance 112 may be provided on the wall of the chamber body 110. The substrate 5 to be processed is brought into the substrate processing space 111 within the chamber body 110 from the outside of the chamber body 110 through the substrate entrance 112. The processed substrate 5 is taken out from the substrate processing space 111 to the outside of the chamber body 110. The substrate entrance 112 is opened and closed by an entrance opening/closing unit 120.

The chamber body 110 has an exhaust port 113 that communicates with the substrate processing space 111. The exhaust port 113 is provided at the bottom of the chamber body 110. An exhaust unit 130 that performs an exhaust function is connected to the exhaust port 113. Due to the exhaust function of the exhaust unit 130, the substrate processing space 111 may be depressurized to perform a substrate processing process under a vacuum atmosphere. In addition, byproducts generated during the substrate processing process, gases remaining in the substrate processing space 111, etc. may be discharged to the outside. For example, the exhaust unit 130 may include an exhaust line connected to the exhaust port 113 and a vacuum pump connected to the exhaust line.

The process chamber 100 further includes a liner 140 provided on the inner surface of the chamber body 110. The liner 140 may safely protect the inner surface of the chamber body 110 that defines the substrate processing space 111. That is, the liner 140 may prevent the inner surface of the chamber body 110 from being damaged by byproducts generated during a substrate processing process, gases remaining in the substrate processing space 111, etc. For example, the liner 140 may be provided along the inner wall of the chamber body 110, and an opening may be provided at a portion corresponding to the substrate entrance 112 to allow the introduction and removal of the substrate 5 by communicating with the substrate entrance 112.

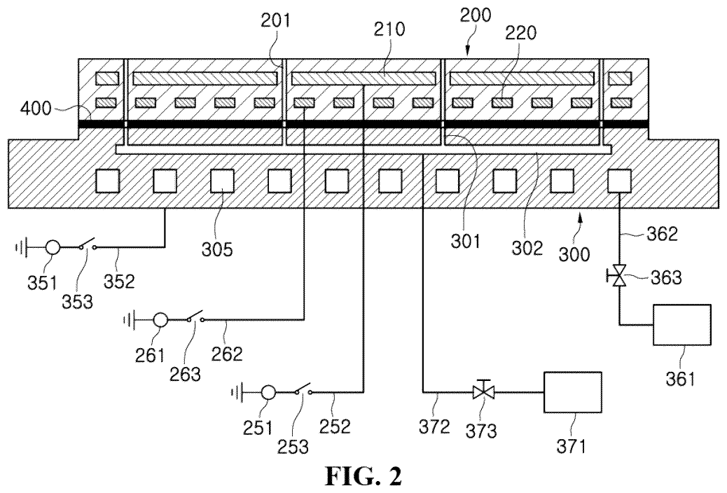

The substrate support assembly 10 is illustrated in FIG. 2. The substrate support assembly 10 is installed inside the chamber body 110. More specifically, the substrate support assembly 10 supports the substrate 5 in the substrate processing space 111, and for this purpose, is disposed in a lower region of the substrate processing space 111. Referring to FIGS. 1 and 2, the substrate support assembly 10 includes a substrate chuck 11, a focus ring 12, a lower cover 13, and an insulating member 14. The substrate chuck 11 constitutes a substrate support unit.

The substrate chuck 11 is an electrostatic chuck (ESC). The electrostatic chuck 11 includes: a chuck body 200 for chucking the substrate 5 with electrostatic force; a chuck base 300 that supports the chuck body 200 from below; and a heat transfer layer 400 interposed between the upper chuck body 200 and the lower chuck base 300.

The chuck body 200 is provided to have a support upper surface on which the substrate 5 is placed, and is mounted on a chuck base 300. The chuck base 300 includes a cooling element (see reference numeral 305) that controls the temperature of the substrate 5 on the chuck body 200 by controlling the temperature of the chuck body (200) during a process of performing a substrate processing process. The heat transfer layer 400 is a silicone-based bonding layer containing silicone, and may mutually bond the chuck body 200 and the chuck base 300 and perform heat transfer between the chuck body 200 and the chuck base 300.

The chuck body 200 is provided as a non-conductive material. For example, the chuck body 200 may be provided in a plate shape having the support upper surface and a predetermined thickness with a dielectric substance. The chuck body 200 includes a chuck electrode 210 and a heating element (see reference numeral 220).

The chuck electrode 210 is provided inside the chuck body 200. That is, the chuck electrode 210 is embedded in the chuck body 200. A chuck power supply 251 is electrically connected to the chuck electrode 210 through a chuck power supply line 252. The chuck power supply 251 includes a direct current power supply. A chuck power supply switch 253 is applied between the chuck electrode 210 and the chuck power supply 251. The chuck power supply switch 253 may be provided on the chuck power supply line 252. In addition, the chuck electrode 210 and the chuck power supply 251 may be electrically connected to each other or released from each other by the on and off operations of the chuck power supply switch 253. When the chuck power supply switch 253 is turned on, an electrostatic force is generated between the substrate 5 and the chuck electrode 210. While a substrate processing process is being performed, the substrate 5 may be chucked to the chuck body 200 due to the electrostatic force thus generated.

The heating element is a heater 220. The heater 220 is provided inside the chuck body 200. The heater 220 may be positioned below the chuck electrode 210. A heater power source 261 is electrically connected to the heater 220 through a heater power line 262. The heater 220 may be configured to generate high-temperature heat by resisting current from the heater power source 261. For example, the heater 220 may include a coil formed in a spiral shape. A heater power switch 263 is applied between the heater 220 and the heater power source 261. The heater power switch 263 may be provided on the heater power line 262. The heater 220 and the heater power source 261 may be electrically connected to each other or disconnected from each other by an on and off operation of the heater power switch 263. While a substrate processing process is performed, when the heater power switch 263 is turned on, heat is generated from the heater 220. The generated heat is transferred to the substrate 5 through the chuck body 200, and the substrate 5 may be maintained at a temperature required for the substrate processing process by the transferred heat.

The chuck base 300 includes a conductive material having excellent heat and electricity conductivity. For example, the material of the chuck base 300 may be a metal, specifically, aluminum. A high-frequency power source 351 is electrically connected to the chuck base 300 through a high-frequency power line 352. For example, the high-frequency power source 351 may be an RF power source. A high-frequency power switch 353 is applied between the chuck base 300 and the high-frequency power source 351. The high-frequency power switch 353 may be provided on the high-frequency power line 352, and the chuck base 300 and the high-frequency power source 351 may be electrically connected to each other or electrically disconnected from each other by the on and off operation of the high-frequency power source switch 353. When the operating state of the high-frequency power source switch 353 is on, high-frequency power from the high-frequency power source 351 is supplied to the chuck base 300. Accordingly, the chuck base 300 may function as a lower electrode constituting the electromagnetic field forming unit.

The cooling element is applied to the inside of the chuck base 300 and is provided as a cooling path 305 through which a cooling fluid circulates. The electrostatic chuck 11 including the chuck base 300 may be provided to have a circular structure corresponding to the substrate (wafer), and the cooling path 305 may be formed in an arc shape. The cooling fluid may be a liquid. For example, the cooling fluid may be coolant. The cooling fluid is supplied at a set pressure into the cooling path 305 by a cooling fluid supply unit. The cooling fluid supply unit includes a cooler (not shown), a cooling fluid supply source 361, a cooling fluid supply line 362, and an on/off valve 363.

The cooler cools the cooling fluid to a set temperature. For example, the set temperature may be lower than room temperature. The cooler may be provided to the cooling fluid supply source 361 to cool the cooling fluid within the cooling fluid supply source 361 or may be provided on the cooling fluid supply line 362 to cool the cooling fluid flowing along the cooling fluid supply line 362. The cooling fluid supply source 361 is connected to the cooling path 305 through the cooling fluid supply line 362. The cooling fluid supply source 361 may be configured to provide a storage space in which the cooling fluid is stored therein and to provide the stored cooling fluid to the cooling path 305 through the cooling fluid supply line 362 at a set pressure. The on/off valve 363 is provided on the cooling fluid supply line 362 to open and close the cooling fluid supply line 362 and control the flow rate of the cooling fluid flowing along the cooling fluid supply line 362. Although not shown, the cooling fluid supply unit further includes a cooling fluid return line for returning cooling fluid from the cooling path 305 to the cooling fluid supply source 361.

When performing a substrate processing process, a cooling fluid is cooled to a set temperature by the cooler, supplied to the cooling path 305 at a set pressure by the cooling fluid supply source 361, and flows along the cooling path 305 at a set flow rate to cool the chuck base 300 through heat transfer with the chuck base 300. Then, the cooled chuck base 300 cools the chuck body 200 and the substrate 5 placed on the support upper surface of the chuck body 200. Accordingly, the substrate processing apparatus according to the embodiment of the present disclosure may maintain the substrate 5 at a temperature required for the substrate processing process by using the cooling fluid. In this process, heat transfer may be performed between the chuck body 200 and the chuck base 300 through the heat transfer layer 400.

The chuck body 200 is configured to have upper supply passages 201 that supply a heat transfer fluid to the lower surface of the substrate 5 placed on the support upper surface. These upper supply passages 201 are arranged at intervals so as to be spaced apart from each other, and are formed in a shape that penetrates the chuck body 200 in the vertical direction. The chuck base 300 is configured to have lower supply passages 301 that are connected to the upper supply passages 201, and a distribution path 302 that connects these lower supply passages 301. The lower supply passages 301 are provided in a shape that extends from the inside of the chuck base 300 to the upper surface of the chuck base 300 and are provided in a number and position corresponding to the upper supply passages 201, so that the lower supply passages 301 may be respectively connected to the upper supply passages 201. The lower supply passages 301 may be connected to each other through the distribution path 302 at the lower ends thereof. For example, the lower supply passages 301 and the distribution path 302 may be arranged above the cooling path 305 inside the chuck base 300. Although not shown, respective sealing members providing airtightness may be interposed between the upper supply passages 201 and the lower supply passages 301. For example, the sealing members may be respectively provided at the upper ends of the lower supply passages 301.

A heat transfer fluid supply unit supplies a heat transfer fluid to the distribution path 302. The heat transfer fluid may include an inert gas. For example, the inert gas may include helium (He). The heat transfer fluid supply unit includes a heat transfer fluid supply source 371, a heat transfer fluid supply line 372, and an on/off valve 373. The heat transfer fluid supply source 371 is connected to the distribution path 302 through the heat transfer fluid supply line 372. In performing a substrate processing process, the heat transfer fluid supply source 371 is operated to supply the heat transfer fluid when the substrate 5 is chucked by the chuck body 200, thereby supplying the heat transfer fluid to the distribution path 302 through the heat transfer fluid supply line 372. The heat transfer fluid is sequentially supplied to the lower surface of the substrate 5 through the lower supply passages 301 and the upper supply passages 201. The heat transfer fluid supplied to the lower surface of the substrate 5 may perform heat transfer between the substrate 5 and the chuck body 200. The on/off valve 373 of the heat transfer fluid supply unit is provided on the heat transfer fluid supply line 372, and may open and close the heat transfer fluid supply line 372 and control the flow rate of the heat transfer fluid supplied to the distribution path 302.

The chuck body 200 is formed such that the support upper surface supporting the substrate 5 is smaller in size than the size (diameter) of the substrate 5, so that the edge region of the substrate 5 supported by the chuck body 200 may protrude outwardly from the chuck body 200. A focus ring 12 is arranged around the chuck body 200. The focus ring 12 has an upper surface inner portion and an upper surface outer portion, and the upper surface outer portion is provided to be higher than the upper surface inner portion, whereas the upper surface inner portion has the same height as the support upper surface of the chuck body 200. In the focus ring 12, the upper surface inner portion may support an edge region of the substrate 5 on the chuck body 200, which deviates from the support upper surface of the chuck body 200, and the upper surface outer portion may surround the substrate 5 on the chuck body 200. Due to the focus ring 12, by controlling the electromagnetic field so that the density of plasma is uniformly distributed over the entire area of the substrate 5, the plasma may be uniformly formed over the entire area of the substrate 5, thereby etching the substrate 5 more uniformly.

A lower cover 13 constitutes the lower part of the substrate support assembly 10 and is positioned upwardly spaced from the bottom of the chamber body 110. The lower cover 13 may have an open space formed therein and a bottom surface provided with a metal material.

The insulating member 14 is provided to cover the open upper part of the lower cover 13 between the electrostatic chuck 11 and the lower cover 13 and to insulate the chuck base 300 and the lower cover 13. The insulating member 14 may include an insulator for electrical insulation.

The shower head 600 is installed on the ceiling side of the chamber body 110, is positioned to face the electrostatic chuck 11, and discharges a process gas from the process gas supply unit 650 at a predetermined pressure to provide the process gas to the substrate processing space 111. The shower head 600 includes a circular shower plate 610 and a cylindrical support member 620.

The shower plate 610 may be positioned at a height spaced downward from the ceiling of the chamber body 110. The shower plate 610 has a plurality of process gas discharge holes 611 for discharging process gas downward. The process gas discharge holes 611 are formed so as to penetrate the shower plate 610 in the up and down direction (vertical direction) throughout the entire shower plate 610, and are provided in a number and pattern to be able to uniformly supply and distribute the process gas to the substrate processing space 111. The shower plate 610 is provided as metal, and may be electrically connected to a high-frequency power source or grounded to function as an upper electrode constituting the electromagnetic field forming unit.

The support member 620 may be provided as a non-metallic material. The support member 620 may be mounted on the ceiling of the chamber body 110 and may support the edge portion of the shower plate 610. The support member 620 is provided to seal the gap between the ceiling of the chamber body 110 and the upper surface of the shower plate 610.

The space within the shower head 600 defined by the shower plate 610 and the support member 620 in the shower head 600 is a buffer space 630 into which a process gas from the process gas supply unit 650 is introduced and that communicates with the process gas discharge holes 611.

The process gas supply unit 650 supplies a process gas required for a substrate processing process to the shower head 600 when performing the substrate processing process. The process gas supply unit 650 may include a process gas supply source 660, a process gas supply nozzle 670, a process gas supply line 680, and a flow rate control valve 690. The process gas supply source 660 is connected to the process gas supply nozzle 670 through the process gas supply line 680 and may provide the process gas to the process gas supply nozzle 670 at a predetermined pressure. The process gas supply nozzle 670 is installed on the ceiling of the chamber body 110, and is connected to the shower head 600 to supply the process gas to the buffer space 630 in the shower head 600. The flow rate control valve 690 is provided on the process gas supply line 680. The flow rate of the process gas supplied to the shower head 600 sequentially through the process gas supply line 680 and the process gas supply nozzle 670 may be controlled by the flow rate control valve 690.

The electromagnetic field forming unit constitutes a plasma generator together with the shower head 600 and the process gas supply unit 650. The electromagnetic field forming unit is configured to generate plasma in a CCP (capacitively coupled plasma) manner by including an upper electrode and a lower electrode arranged vertically within the substrate processing space 111. As previously mentioned, the upper electrode may be provided as the shower plate 610, and the lower electrode may be provided as the chuck base 300. Alternatively, the electromagnetic field forming unit may be configured to generate plasma in an ICP (inductively coupled plasma) manner, and may include an antenna for this purpose.

The baffle unit 700 includes a baffle. The baffle may be provided along the periphery of the substrate support assembly 10 and may be arranged between the inner wall of the chamber body 110 and the periphery of the electrostatic chuck 11. The baffle is formed to have process gas passage holes. The process gas supplied to the substrate processing space 111 may pass through the process gas passage holes of the baffle and be discharged to the exhaust port 113. The flow of the process gas in the substrate processing space 111 may be controlled according to the shapes of the baffle and the process gas passage holes, etc.

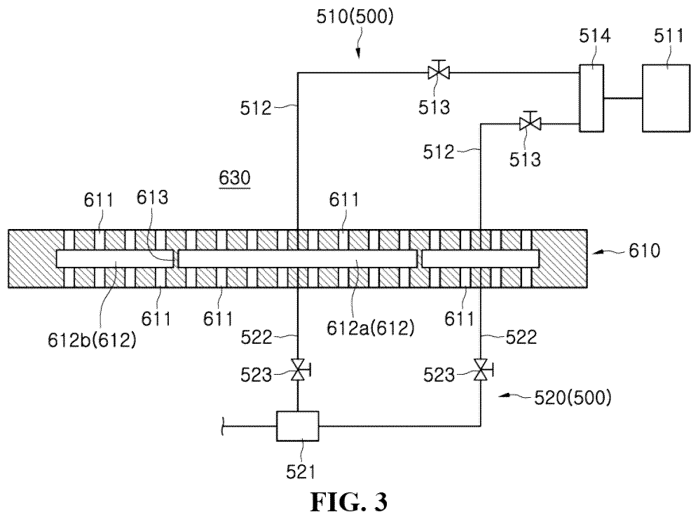

FIGS. 3 to 8 show the configuration, operation, etc. of the shower head assembly including the shower head 600. Referring to FIG. 3, the substrate processing apparatus according to an embodiment of the present disclosure further includes a blocking airflow forming unit 500 that blocks the discharge of process gas by forming a blocking airflow that flows at a faster speed than the process gas in a horizontal direction perpendicular to the discharge direction of the process gas inside the shower head 600. The blocking airflow forming unit 500 and the shower head 600 constitute the shower head assembly.

The blocking airflow forming unit 500 forms a blocking airflow having a predetermined thickness using an inert gas (e.g., nitrogen (N2)), and the shower head 600 is configured such that the blocking airflow passes horizontally through the interior of the shower head 600. Specifically, the shower head 600 is configured so that the blocking airflow passes horizontally through the interior of the shower plate 610.

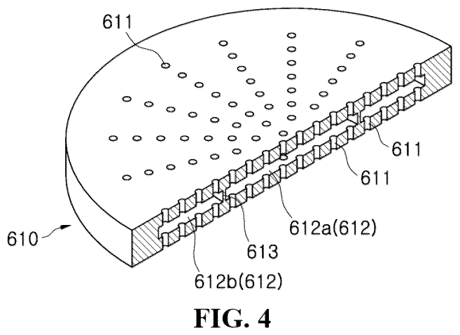

A cross-sectional shape of the shower plate 610 as seen from the front is illustrated in a perspective view in FIG. 4. Referring to FIG. 4, the shower plate 610 has a cavity 612 formed therein that extends horizontally and communicates with the process gas discharge holes 611, and the blocking airflow forming unit 500 forms a blocking airflow in the cavity 612 of the shower plate 610.

The shower plate 610 includes at least one partition 613, and the cavity 612 is partitioned by the partition 613. The partition 613 is provided to divide the cavity 612 into a plurality of blocked spaces 612a and 612b communicating with the process gas discharge holes 611 according to the region of the shower plate 610, and the blocking airflow forming unit 500 is configured to individually form the blocking airflow in the blocked spaces 612a and 612b of the cavity 612.

The partition 613 is formed to have a circular structure and divides the shower plate 610 into a plurality of regions in the circumferential direction, and provides concentric blocked spaces 612a, 612b that communicate with the process gas discharge holes 611 for each region of the shower plate 610.

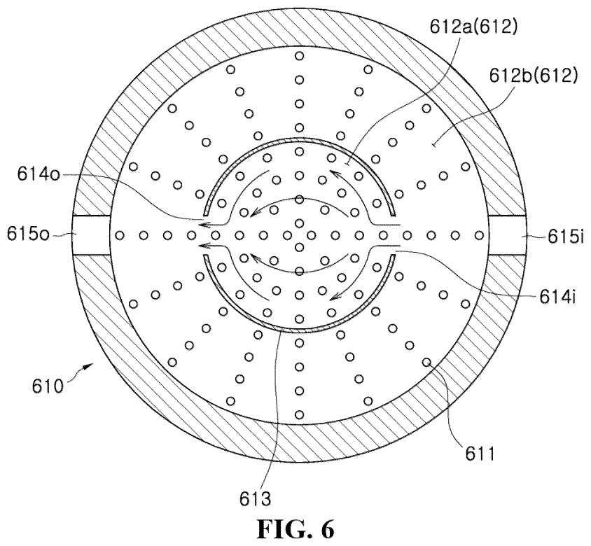

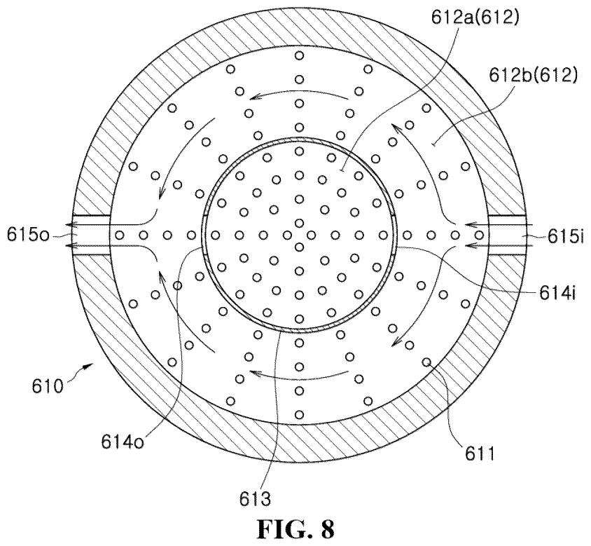

A cross-sectional shape of the shower plate 610 as seen from above is illustrated in FIGS. 6 and 8. As an example, one partition 613 may be provided. Referring to FIGS. 6 and 8, one partition 613 may be arranged to divide the shower plate 610 into a central region including process gas discharge holes in the central portion and a peripheral region including process gas discharge holes in the peripheral portion, thereby dividing the cavity 612 into the central blocked space 612a communicating with the process gas discharge holes in the central region of the shower plate 610 and the peripheral blocked space 612b communicating with the process gas discharge holes in the peripheral region of the shower plate 610. As another example, two partitions 613 may be provided. The two partitions may be arranged to divide the cavity 612 into a central blocked space, a peripheral blocked space, and an intermediate blocked space between the central blocked space and the peripheral blocked space.

Referring to FIGS. 6 and 8, the shower plate 610 has gas supply ports 614i, 615i through which gas of the blocking airflow is supplied and gas discharge ports 614o, 615o through which gas of the blocking airflow is discharged.

The gas of the blocking airflow is supplied to the blocked spaces 612a, 612b through the gas supply ports 614i, 615i and discharged from the blocked spaces 612a, 612b through the gas discharge ports 614o, 615o. Of course, for this purpose, the gas supply ports 614i, 615i and the gas discharge ports 614o, 615o are provided to communicate with the blocked spaces 612a, 612b.

The gas supply port 615i and the gas discharge port 615o communicating with the outermost blocked space among the concentric blocked spaces 612a and 612b are formed so as to penetrate the shower plate 610 in a horizontal direction from the side, and are arranged opposite each other to naturally induce and maintain the horizontal flow of gas of the blocking airflow constant. The gas supply port 614i and the gas discharge port 614o communicating with the inner blocked space among the concentric blocked spaces 612a and 612b are formed so as to penetrate the partition 613 in a horizontal direction from the side, and are arranged opposite each other to naturally induce and maintain the horizontal flow of gas of the blocking airflow constant.

Referring to FIGS. 3, 5, and 7, the blocking airflow forming unit 500 includes a gas supply module 510 that supplies gas of the blocking airflow to gas supply ports 614i and 615i, and a gas discharge module 520 that controls the amount of gas discharged through gas discharge ports 614o and 615o.

The gas supply module 510 may include a gas supply source 511, a plurality of gas supply lines 512, a plurality of on/off valves 513, and a pressure controller 514.

The gas supply source 511 is connected to the gas supply ports 614i, 615i through the gas supply lines 512. The gas supply source 511 may provide a space where gas is stored. The gas supply source 511 may provide gas at a predetermined pressure to form a blocking airflow flowing at a set velocity (a velocity faster than the velocity of a process gas) in the blocked spaces 612a, 612b. The gas supply lines 512 are respectively connected to the gas supply ports 614i, 615i. Among the gas supply lines 512, the gas supply line connected to the gas supply port 614i located within the shower plate 610 may penetrate the shower plate 610 in a form that takes into account smooth flow of process gas, smooth formation of airflow, etc. The on/off valves 513 of the gas supply module 510 are respectively provided in the gas supply lines 512, and may open/close the gas supply lines 512 and control the flow rate of gas supplied along the gas supply lines 512. The pressure controller 514 may receive gas from the gas supply source 511, control the pressure of the gas, and provide the gas with the controlled pressure to the gas supply lines 512.

The gas discharge module 520 may include a suction power generation source 521, a plurality of gas discharge lines 522, and a plurality of on/off valves 523.

The suction power generation source 521 is connected to the gas discharge ports 614o and 615o through the gas discharge lines 522. The suction power generation source 521 may include a suction fan or suction pump that generates a predetermined suction power. The suction power generation source 521 may accelerate the rate at which gas is discharged from the blocked spaces 612a and 612b using suction power, thereby suppressing the phenomenon in which the flow rate of the blocking airflow is reduced in the blocked spaces 612a and 612b. The gas discharge lines 522 are connected to the gas discharge ports 614o and 615o, respectively. Among the gas discharge lines 522, the gas discharge line connected to the gas discharge port 614o located in the shower plate 610 penetrates the shower plate 610 in a form that takes into account the smooth flow of process gas and the smooth formation of airflow. The on/off valves 523 of the gas discharge module 520 are respectively provided in the gas discharge lines 522, and may open and close the gas discharge lines 522 and may control the flow rate of the gas discharged along the gas discharge lines 522. Depending on implementation conditions, etc., the gas discharge module 520 may be configured excluding the suction power generation source 521.

According to the shower head assembly as described, when performing a substrate processing process, gas is supplied to all of the blocked spaces 612a and 612b of the shower plate 610 to form a blocking airflow to block the discharge of process gas through the process gas discharge holes 611 of the shower plate 610, thereby immediately stopping the supply of the process gas to the substrate processing space.

In addition, while the process gas supply unit 650 is maintained to supply process gas, gas is supplied to both the blocked spaces 612a and 612b to form a blocking airflow, and afterwards, the supply of the gas to the blocked spaces 612a and 612b is stopped to remove the blocking airflow from the blocked spaces 612a and 612b, thereby allowing the supply of the process gas to the substrate processing space to begin immediately. When performing a substrate processing process, by repeating the supply and interruption of the supply of gas to all of the blocked spaces 612a and 612b (i.e., repeating the supply and interruption of the supply of process gas), the processing speed (reaction speed) for a substrate may be controlled in pulse form. In this control process, in order to form the blocking airflow to have a stable thickness in terms of blocking the process gas, the gas discharge module 520 may be operated to allow gas to be discharged from the blocked spaces 612a and 612b at a time lag from the point of gas supply when gas is supplied to the blocked spaces 612a and 612b.

The shower head assembly as described may, when a substrate processing process is performed, control the distribution of process gas in the substrate processing space 111 by forming a blocking airflow in the blocked space selected from the blocked spaces 612a and 612b, and through this a substrate may be processed more uniformly.

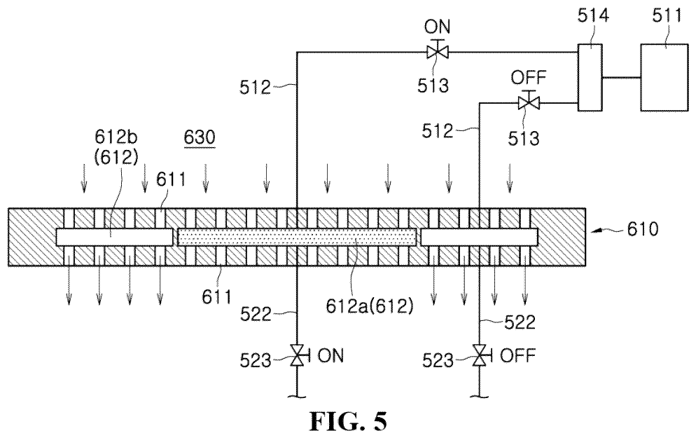

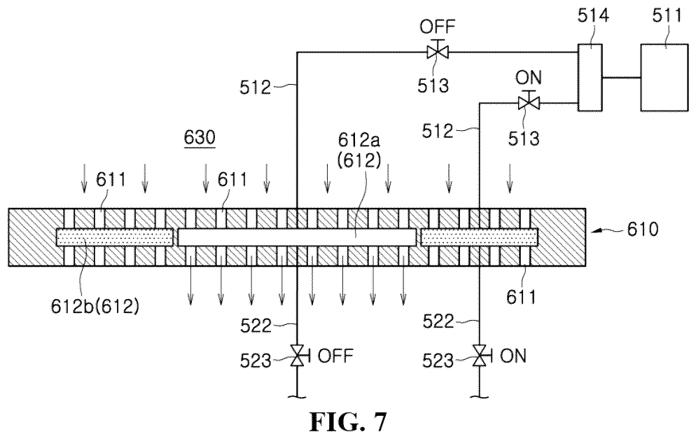

In relation to this, FIGS. 5 and 6 show a state in which a process gas is discharged through process gas discharge holes 611 positioned relatively on the periphery on the shower plate 610, and FIGS. 7 and 8 show a state in which a process gas is discharged through process gas discharge holes 611 positioned relatively centrally on the shower plate 610.

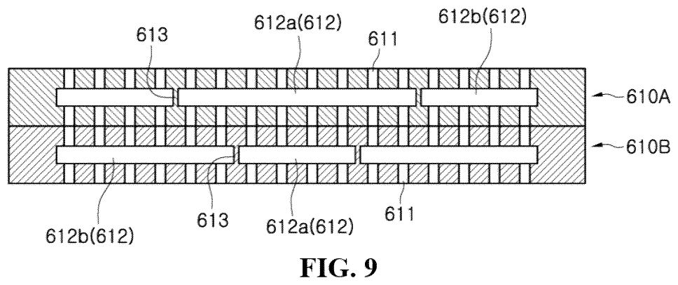

FIG. 9 shows a modified example of the shower head assembly. Referring to FIG. 9, the shower head of the shower head assembly may be configured to have a plurality of shower plates 610A and 610B, unlike as described above.

The shower plates 610A and 610B may be stacked so that the process gas discharge holes 611 match each other. In addition, the shower plates 610A and 610B may be configured so that the areas occupied by the partitioned blocked spaces 612a and 612b are different from each other or the sizes of the occupied areas are different from each other. Of course, the blocking airflow forming unit may individually form a blocking airflow in the blocked spaces 612a and 612b of the shower plates 610A and 610B.

According to this modified example, the amount of process gas discharged from the shower head may be adjusted more diversely for each area of the shower head, thereby processing a substrate more uniformly.

Although the present disclosure has been described above, the present disclosure is not limited to the disclosed embodiments and the attached drawings, and various modifications may be made by those skilled in the art within the scope that does not depart from the technical spirit of the present disclosure. Furthermore, the technical described in the embodiments of the present disclosure may be implemented independently, or two or more may be implemented in combination with each other.

For example, although the blocking airflow is described as passing horizontally through the shower plate 610 inside the shower head 600, the shower head 600 may be configured so that the blocking airflow passes horizontally through the buffer space 630 inside the shower head 600 rather than the shower plate 610) Alternatively, the shower head 600 may be configured so that the blocking airflow may pass horizontally through both the shower plate 610 and the buffer space 630 inside the shower head 600, and the blocking airflow forming unit 500 may be configured so that the blocking airflow is selectively formed in the shower plate 610 and the buffer space 630.

### DESCRIPTION OF NUMERALS

5: substrate
10: substrate support assembly
100: process chamber
500: blocking airflow forming unit
510: gas supply module
520: gas discharge module
600: shower head
610: shower plate
611: process gas discharge hole
612: cavity
613: partition
620: support member
630: buffer space
650: process gas supply unit

What is claimed is:

1. A shower head assembly, comprising:
a shower head for discharging a process gas into a substrate processing space; and
a blocking airflow forming unit configured to block discharge of the process gas by forming a blocking airflow flowing in a direction intersecting a discharge direction of the process gas inside the shower head.

2. The shower head assembly of claim 1,
wherein the shower head is configured to allow the blocking airflow to pass therethrough.

3. The shower head assembly of claim 2,
wherein the shower head has a gas supply port through which a gas of the blocking airflow is supplied and a gas discharge port through which the gas of the blocking airflow is discharged, provided opposite to each other.

4. The shower head assembly of claim 3,
wherein the blocking airflow forming unit comprises:
a gas supply module configured to supply the gas to the gas supply port; and
a gas discharge module configured to regulate an amount of the gas discharged through the gas discharge port.

5. The shower head assembly of claim 1,
wherein the shower head comprises a shower plate, wherein the shower plate has a plurality of process gas discharge holes passing therethrough, and a cavity communicating with the plurality of process gas discharge holes is formed therein, and
wherein the blocking airflow forming unit forms the blocking airflow in the cavity.

6. The shower head assembly of claim 5,
wherein the shower plate includes at least one partition dividing the cavity into a plurality of blocked spaces communicating with the plurality of process gas discharge holes for each region of the shower plate, and
wherein the blocking airflow forming unit forms the blocking airflow in the plurality of blocked spaces individually.

7. The shower head assembly of claim 6,
wherein the at least one partition is provided to circumferentially partition the cavity.

8. The shower head assembly of claim 6,
wherein the shower plate has a plurality of gas supply ports and gas discharge ports communicating with the plurality of blocked spaces, and
wherein the blocking airflow forming unit comprises:
a gas supply module configured to supply a gas of the blocking airflow to the plurality of gas supply ports; and
a gas discharge module configured to regulate an amount of the gas discharged through the gas discharge ports.

9. The shower head assembly of claim 8,
wherein the gas discharge module is maintained in a state to block discharge of the gas through the gas discharge ports, and, when the gas is supplied by the gas supply module to any blocked space selected among the plurality of blocked spaces, is operated to allow the discharge of the gas from the selected blocked space at a time lag.

10. The shower head assembly of claim 6,
wherein by forming the blocking airflow in any blocked space selected among the plurality of blocked spaces, distribution of the process gas in the substrate processing space is controlled.

11. The shower head assembly of claim 1,
wherein the shower head comprises a shower plate having a plurality of process gas discharge holes, and is configured to have a buffer space provided for introducing the process gas and communicating with the plurality of process gas discharge holes, and
wherein the blocking airflow forming unit forms the blocking airflow in the buffer space.

12. The shower head assembly of claim 11,
wherein the shower head is configured to allow the blocking airflow to pass through the buffer space.

13. The shower head assembly of claim 5,
wherein the shower plate is provided in plural,
wherein the shower plates are stacked so that the plurality of process gas discharge holes match each other, and each of the shower plates includes at least one partition dividing the cavity into a plurality of blocked spaces in a circumferential direction, with the plurality of blocked spaces being arranged in different areas of the shower plates, and
wherein the blocking airflow forming unit individually forms the blocking airflow in the plurality of blocked spaces of the shower plates.

14. The shower head assembly of claim 1,
wherein a gas of the blocking airflow is an inert gas.

15. The shower head assembly of claim 1,
wherein a flow rate of the blocking airflow is faster than a flow rate of the process gas.

16. A substrate processing apparatus, comprising:
a process chamber configured to provide a substrate processing space;
a substrate support unit configured to support a substrate in the substrate processing space;
a shower head configured to discharge a process gas from a process gas supply unit into the substrate processing space;
a plasma source configured to generate plasma from the process gas supplied to the substrate processing space; and
a blocking airflow forming unit configured to block discharge of the process gas by forming a blocking airflow flowing in a direction intersecting a discharge direction of the process gas inside the shower head.

17. The substrate processing apparatus of claim 16,
wherein the shower head comprises a shower plate having a plurality of process gas discharge holes, has a buffer space provided for introducing the process gas and communicating with the plurality of process gas discharge holes, and is configured to allow the blocking airflow to pass therethrough.

18. The substrate processing apparatus of claim 17,
wherein the shower plate has a cavity formed therein communicating with the plurality of process gas discharge holes, and includes at least one partition dividing the cavity into a plurality of blocked spaces communicating with the plurality of process gas discharge holes for each region of the shower plate, and
wherein the blocking airflow forming unit forms the blocking airflow in the plurality of blocked spaces individually.

19. The substrate processing apparatus of claim 18,
wherein the at least one partition is provided to circumferentially partition the cavity.

20. A substrate processing apparatus, comprising:
a process chamber configured to provide a substrate processing space;
a substrate support unit configured to support a substrate in a lower area of the substrate processing space;
a shower head configured to discharge a process gas supplied from a process gas supply unit onto the substrate supported by the substrate support unit from an upper area of the substrate processing space;
a plasma source configured to generate plasma from the process gas supplied to the substrate processing space; and
a blocking airflow forming unit configured to block discharge of the process gas by forming a blocking airflow flowing at a faster flow rate than that of the process gas in a direction perpendicular to a discharge direction of the process gas inside the shower head,
wherein the shower head comprises a shower plate having a plurality of process gas discharge holes, and has a buffer space provided for introducing the process gas and communicating with the plurality of process gas discharge holes,
wherein the shower plate has a cavity formed therein communicating with the plurality of process gas discharge holes, includes at least one partition dividing the cavity into a plurality of circumferentially partitioned blocked spaces, and has a plurality of gas supply ports and gas discharge ports communicating with the plurality of circumferentially partitioned blocked spaces,
wherein the blocking airflow forming unit is configured to individually supply a gas of the blocking airflow to the plurality of gas supply ports and individually adjust an amount of o the gas discharged through the gas discharge ports, and
wherein the gas of the blocking airflow is an inert gas.
